(19) United States
(12) Patent Application Publication
(10) Pub. No.: US 2005/0253146 A1
(43) Pub. Date: Nov. 17, 2005

(54) [THIN FILM TRANSISTOR ARRAY]

(76) Inventor: Han-Chung Lai, Taoyuan Hsien (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/710,388

(22) Filed: Jul. 7, 2004

(30) Foreign Application Priority Data
Apr. 29, 2004 (TW) 93111982

(51) Int. Cl. H01L 29/04

(52) U.S. Cl. 257/72

(57) ABSTRACT

A thin film transistor array including a substrate, scan lines, data lines, thin film transistor, pixel electrodes, bottom electrodes and connecting conductive layers. The scan lines and the data lines are disposed over the substrate and is divided to pixel areas by the scan lines and the data lines. Each thin film transistor is disposed in one of the pixel areas and is driven by the scan lines and the data lines correspondingly. Each pixel electrode is disposed in one of the pixel areas and is electrically connected to one of the thin film transistors correspondingly. A portion of each pixel electrode is located above one of the scan lines. Each bottom electrode is disposed between one of the pixel electrodes and one of the scan lines. Each connecting conductive layer is located over and electrically connected between one of the bottom electrodes and one of the scan lines correspondingly.

### CROSS REFERENCE TO RELATED APPLICATIONS

This application claims the priority benefit of Taiwan application serial no. 93111982, filed Apr. 29, 2004.

### BACKGROUND OF INVENTION

1. Field of the Invention

The present invention relates to a thin film transistor array (TFT array). More particularly, the present invention relates to a thin film transistor array (TFT array) having a Metal-Insulator-ITO (MII) type storage capacitor.

2. Description of Related Art

The proliferation of multi-media systems in our society depends to a large extent on the progressive development of semiconductor devices and display devices. Display devices such as the cathode ray tube (CRT) have been used for quite some time due to its remarkable display quality, reliability and low cost. Although the conventional CRT has many advantages, the design of the electron gun renders it heavy, bulky and energy wasting. Moreover, there is always some potential danger of hurting viewer's eyes due to its emission of some radiation. With big leaps in the techniques of manufacturing semiconductor devices and opto-electronics devices, high picture quality, slim, low power consumption and radiation-free displays such as the thin film transistor liquid crystal displays (TFT-LCD) have gradually become mainstream display products.

Generally, a color TFT-LCD includes a color filter (C/F), a TFT array and a liquid crystal layer disposed therebetween. The TFT array includes a plurality of thin film transistors, which is arranged in an area array and is driven by a plurality of scan lines and data lines. Each thin film transistor is disposed in a pixel area and is electrically connected to a corresponding pixel electrode formed by indium tin oxide (ITO), indium zinc oxide (IZO) or other transparent conductive materials. Each thin film transistor is used to drive the liquid crystal layer to show various gray levels. Furthermore, in a pixel of the conventional TFT array, a storage capacitor may be formed by a pixel electrode, the corresponding scan line and a dielectric layer (e.g. a gate insulator and/or a passivation layer) therebetween. Also, the storage capacitor can be formed by a pixel electrode, a common line and a dielectric layer therebetween to provide better picture quality. In the prior art, storage capacitor is classified into Metal-Insulator-Metal (MIM) type and Metal-Insulator-ITO (MII) type, which are described as follow.

FIG. 1 is a cross-sectional view of a conventional MIM type storage capacitor. Referring to FIG. 1, in a conventional pixel structure, a MIM type storage capacitor is coupled by a scan line (not shown) and an upper electrode 120 or is coupled by a common line 100 and an upper electrode 120. It should be noted that the common line 100 (or the scan line) and the upper electrode is electrical isolated by a gate insulator 110 therebetween in the MIM type storage capacitor. Therefore, capacitance of the MIM type storage capacitor relates to thickness of the gate insulator 110. In other words, the smaller the thickness of the gate insulator 110, the larger the capacitance Cst of the MIM type storage capacitor. Furthermore, a pixel electrode 140 is electrically connected to the upper electrode 120 through a contact window 132 formed in a passivation layer 130.

FIG. 2 is a cross-sectional view of a conventional MII type storage capacitor. Referring to FIG. 2, in a conventional pixel structure, a MII type storage capacitor is coupled to a scan line (not shown) and a pixel electrode 230 or is coupled to a common line 200 and a pixel electrode 230. Compared with the MIM type storage capacitor, the common line 200 (or the scan line) and the pixel electrode 230 is electrically isolated by a gate insulator 210 and a passivation layer 220 therebetween in the MII type storage capacitor. Therefore, capacitance of the MII type storage capacitor relates to total thickness of the gate insulator 210 and the passivation layer 220. In other words, the smaller the total thickness of the gate insulator 210 and the passivation layer 220, the larger the capacitance Cst of the MIM type storage capacitor is.

In the conventional TFT array mentioned above, the thickness of the gate insulator 210 and/or passivation layer 220 must be reduced to obtain a larger capacitance Cst without lowering aperture ratio. However, the reliability of thin film transistors may be affected when the thickness of the gate insulator 210 and/or passivation layer 220 is reduced.

### SUMMARY OF INVENTION

The invention directed to a thin film transistor array, wherein the capacitance of the storage capacitor of each pixel is increased.

The invention is directed to a thin film transistor array, wherein the aperture ratio of each pixel is raised.

According to an embodiment of the present invention, the thin film transistor array including a substrate, a plurality of scan lines, a plurality of data lines, a plurality of thin film transistor, a plurality of pixel electrodes, a plurality of bottom electrodes and a plurality of connecting conductive layers is provides. The scan lines and the data lines are disposed over the substrate and the substrate is defined into a plurality of pixel areas by the scan lines and the data lines. Each thin film transistor is disposed in one of the pixel areas and is driven by the scan lines and the data lines correspondingly. Each pixel electrode is disposed in one of the pixel areas and is electrically connected to one of the thin film transistors correspondingly. A portion of each pixel electrode is located above one of the scan lines. Each bottom electrode is disposed between one of the pixel electrodes and one of the scan lines. Each connecting conductive layer is located over and electrically connected between one of the bottom electrodes and one of the scan lines correspondingly.

According to an embodiment of the present invention, the thin film transistor array including a substrate, a plurality of scan lines, a plurality of data lines, a plurality of thin film transistor, a plurality of pixel electrodes, a plurality of common lines, a plurality of bottom electrodes and a plurality of connecting conductive layers is provided. The scan lines and the data lines are disposed over the substrate and the substrate is defined into a plurality of pixel areas by the scan lines and the data lines. Each thin film transistor is disposed in one of the pixel areas and is driven by the scan lines and the data lines correspondingly. Each pixel electrode is disposed in one of the pixel areas and is electrically connected to one of the thin film transistors correspondingly. The common lines are disposed over the substrate and a portion of each common line is located above one of the common lines. Each bottom electrode is disposed between one of the pixel electrodes and one of the common lines. Each connecting conductive layer is located over and electrically connected between one of the bottom electrodes and one of the common lines correspondingly.

In the thin film transistor array, according to an embodiment of the present invention, the connecting conductive layers are formed over and electrically connected between one of the bottom electrodes and one of the scan lines (or common lines) correspondingly so that a storage capacitor is coupled by the bottom electrode and the pixel electrode. Therefore, compared to the conventional storage capacitor, the capacitance of the storage capacitor disclosed in the present invention is lager with the same coupling area. In other words, a smaller area is needed to obtain a necessary capacitance of the storage capacitor, and therefore aperture ratio of each pixel is raised.

It is to be understood that both the foregoing general description and the following detailed description are exemplary, and are intended to provide further explanation of the invention as claimed.

### BRIEF DESCRIPTION OF DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a cross-sectional view of a conventional MIM type storage capacitor.

FIG. 2 is a cross-sectional view of a conventional MII type storage capacitor.

FIG. 3 is a top view of a thin film transistor array according to an embodiment of the present invention.

FIG. 4 is a cross-sectional view along line A-A′ of FIG. 3.

FIG. 5 is a cross-sectional view of a thin film transistor array according to another embodiment of the present invention.

FIG. 6 is a top view of a thin film transistor array according to still another embodiment of the present invention.

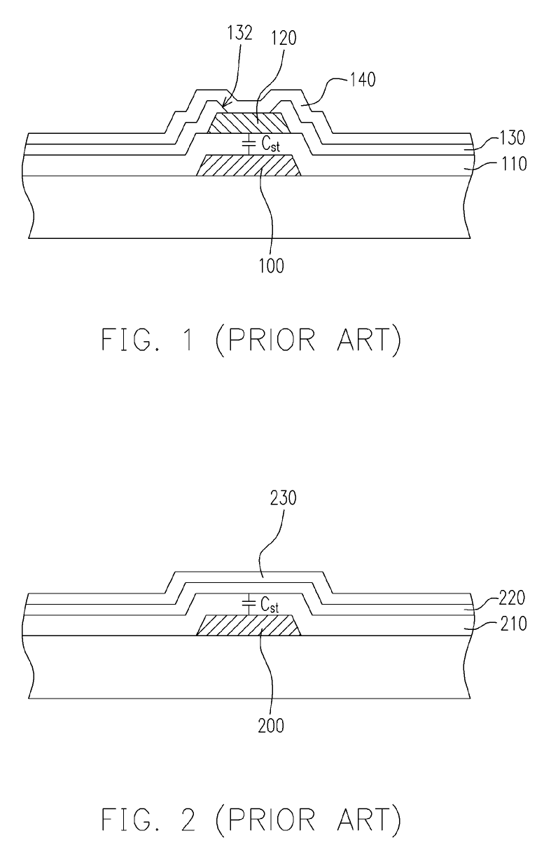

### DETAILED DESCRIPTION

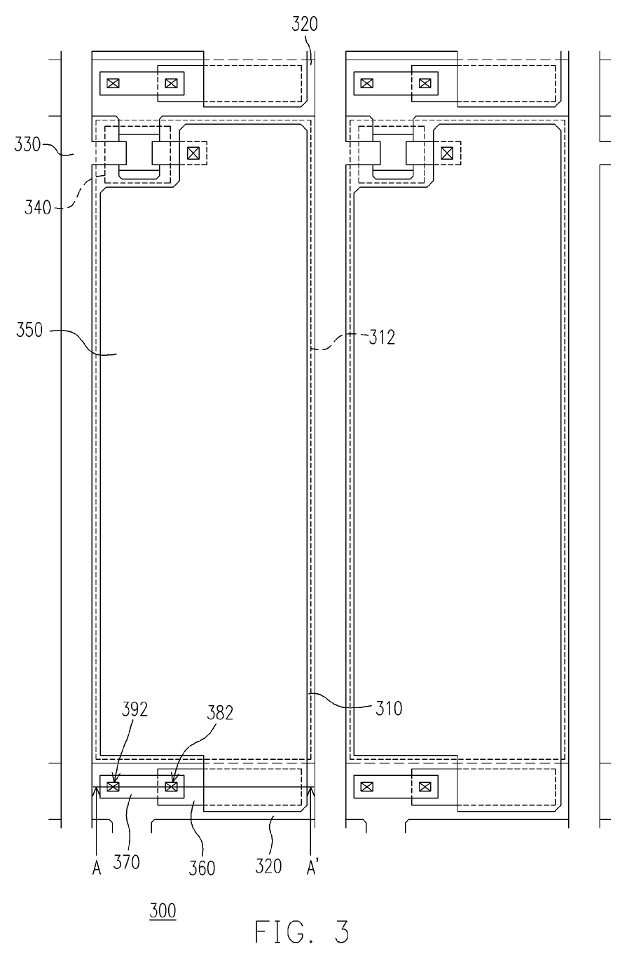

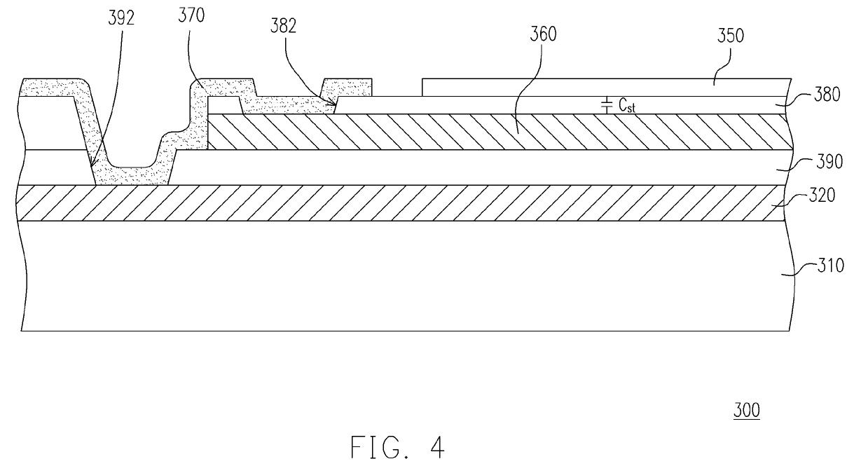

FIG. 3 is a top view of a thin film transistor array according to an embodiment of the present invention; and FIG. 4 is a cross-sectional view along line A-A′ of FIG. 3.

Referring to FIG. 3 and FIG. 4, the thin film transistor array 300 of the present invention includes a substrate 310, a plurality of scan lines 320, a plurality of data lines 330, a plurality of thin film transistor 340, a plurality of pixel electrodes 350, a plurality of bottom electrodes 360 and a plurality of connecting conductive layers 370.

The scan lines 320 and the data lines 330 are disposed over the substrate 310, which is defined into a plurality of pixel areas 312 by the scan lines 320 and the data lines 330. Each thin film transistor 340 is disposed in one of the pixel areas 312 and is driven by the scan lines 320 and the data lines 330 correspondingly. Furthermore, each pixel electrode 350 is disposed in one of the pixel areas 312 and is electrically connected to one of the thin film transistors 340 correspondingly. A portion of each pixel electrode 350 is located above one of the scan lines 320.

Moreover, Each bottom electrode 360 is disposed between one of the pixel electrodes 350 and one of the scan lines 320. The bottom electrodes 360, the data lines 330, the source/drain metal are formed simultaneously. In this embodiment, a passivation layer 380 is formed between the bottom electrodes 360 and the pixel electrodes 350 to electrically isolate the bottom electrodes 360 and the pixel electrodes 350.

In addition, each connecting conductive layer 370 is located over and electrically connected between one of the bottom electrodes 360 and one of the scan lines 320 correspondingly. In this embodiment, a dielectric layer 390 is formed between the bottom electrodes 360 and the scan lines 320. The passivation layer 380 and the dielectric layer 390 comprise a plurality of first contact windows 382 and a plurality of second contact windows 392. Each first contact windows 382 exposes one of the bottom electrode 360, and each second contact window 392 exposes one of the scan lines 320. In this embodiment, each connecting conductive layer 370 is electrically connected to one of the bottom electrodes 360 through one of the first contact windows 382, and each connecting conductive layer 370 is electrically connected to one of the scan lines 320 through one of the second contact windows 392.

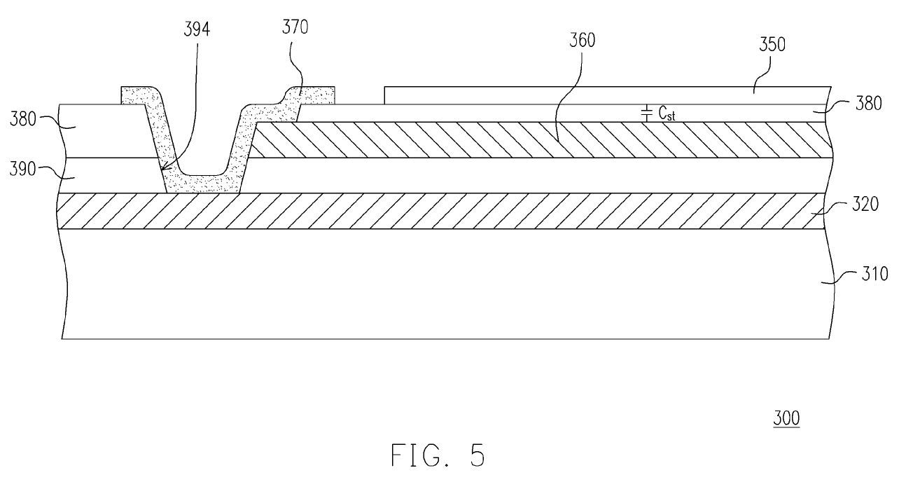

FIG. 5 is a cross-sectional view of a thin film transistor array according to another embodiment of the present invention. Referring to FIG. 4 and FIG. 5, in the embodiment mentioned above, the connecting conductive layers 370 are electrically connected to the bottom electrodes 360 and the scan lines 320 through the first contact windows 382 and the second contact windows 392, respectively (shown in FIG. 4). However, the first contact windows 382 and the second contact windows 392 of the passivation layer 380 and the dielectric layer 390 is only for illustration, the manner of electrical connection between the bottom electrodes 360 and the scan lines 320 is not limited. As shown in FIG. 5, the passivation layer 380 and the dielectric layer 390, for example, comprises a plurality of third contact windows 394, more specifically, only one third contact window 394 is formed in a pixel as shown in FIG. 5. In this embodiment, the third contact window 394 having appropriate size exposes the bottom electrodes 360 and the scan lines 320 simultaneously so that the connecting conductive layer 370 can electrically connect between the bottom electrodes 360 and the scan lines 320 through the third contact window 394.

As described above, a connecting conductive layer 370 is formed over and electrically connected between the bottom electrode 360 and the scan line 320 correspondingly so that a storage capacitor is coupled by the bottom electrode 360 and the pixel electrode 350. In other words, the storage capacitor of the present invention is a MII type storage capacitor.

It should be noted that, in the MII type storage capacitor of the present invention, the passivation layer located between the bottom electrode and the pixel electrode has smaller thickness than the dielectric layer, which is located between the bottom electrode and the upper electrode of conventional storage capacitor. Therefore, compared with the conventional storage capacitor, the capacitance of the storage capacitor disclosed in the present invention is lager with the same coupling area. In other words, a smaller area is needed to obtain a necessary capacitance of the storage capacitor, and therefore aperture ratio of each pixel is raised.

As mentioned above, a Cst on gate structure, i.e. the storage capacitor is formed on a scan line, is illustrated, however, the present invention can also be applied to a Cst on common structure, wherein the storage capacitor is formed on a common line.

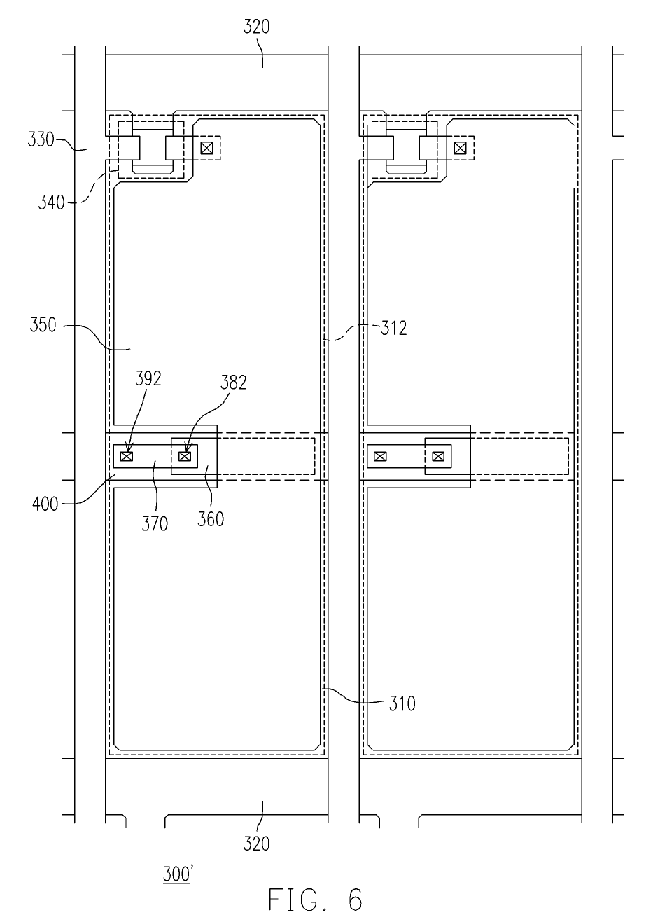

FIG. 6 is a top view of a thin film transistor array according to still another embodiment of the present invention. In FIG. 6, the thin film transistor array 300″ is similar to the thin film transistor array 300 described in FIG. 3, and therefore, only difference therebetween is described as follow.

Referring to FIG. 6, in a Cst on common structure of the present invention, a common line 400 is disposed between two adjacent scan lines 320. In this embodiment, a portion of each pixel electrode 350 is located above the corresponding common line 400, and each bottom electrode 360 is disposed between the pixel electrode 350 and the common line 400. Each connecting conductive layer 370 is located over and electrically connected between the bottom electrode 360 and the common line 400 correspondingly so that a MII type storage capacitor is coupled by the pixel electrode 350 and the bottom electrode 360.

As described above, the material of the connecting conductive layer of the present invention is not limited. To simplify processes, the material of the connecting conductive layer may be identical with the pixel electrode, such as indium tin oxide (ITO) or indium zinc oxide (IZO). In other words, the connecting conductive layer and the pixel electrode for display can be formed together by one patterning process.

Moreover, the concept of the present invention can be applied to a thin film transistor array of a multi-domain vertical alignment liquid crystal display (MVA-LCD) or other type LCDs. In MVA-LCD, patterned slits or protrusions are formed in/on pixel electrodes to form a plurality of domains between two substrates, and therefore, arrangement of liquid crystal between substrates is locally changed so as to improve the viewing angle. When patterning the slits or protrusions, the connecting conductive layer can be formed simultaneously.

As mentioned above, the thin film transistor array of the present invention at least comprises advantages as follow:

1. Compared with the conventional storage capacitor, the capacitance of the storage capacitor disclosed in the present invention is lager with the same coupling area.

2. In the thin film transistor array of the present invention, a smaller area is needed to obtain a necessary capacitance of the storage capacitor, and therefore aperture ratio of each pixel is raised.

3. In the thin film transistor array of the present invention, the connecting conductive layer and the pixel electrode for display can be formed together by the same patterning process so that the manufacturing thereof is simple and practical.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A thin film transistor array, comprising:
a substrate;
a plurality of scan lines, disposed over the substrate;
a plurality of data lines, disposed over the substrate, wherein the substrate is defined into a plurality of pixel areas by the scan lines and the data lines;
a plurality of thin film transistor, driven by the scan lines and the data lines, wherein each thin film transistor is disposed in one of the pixel areas correspondingly;
a plurality of pixel electrodes, wherein each pixel electrode is disposed in one of the pixel areas and is electrically connected to one of the thin film transistors correspondingly, a portion of each pixel electrode is located above one of the scan lines;
a plurality of bottom electrodes, each bottom electrode is disposed between one of the pixel electrodes and one of the scan lines; and
a plurality of connecting conductive layers, each connecting conductive layer is located over and electrically connected between one of the bottom electrodes and one of the scan lines correspondingly.

2. The thin film transistor array of claim 1, further comprising a passivation layer disposed between the pixel electrodes and the bottom electrodes as well as the connecting conductive layer and the bottom electrodes.

3. The thin film transistor array of claim 2, further comprising a dielectric layer disposed between the bottom electrodes and the scan lines.

4. The thin film transistor array of claim 3, wherein the passivation layer and the dielectric layer comprise a plurality of first contact windows and a plurality of second contact windows, and each first contact window exposes one of the bottom electrode, and each second contact window exposes one of the scan lines.

5. The thin film transistor array of claim 4, wherein each connecting conductive layer is electrically connected to one of the bottom electrodes through one of the first contact windows, and each connecting conductive layer is electrically connected to one of the scan lines through one of the second contact windows.

6. The thin film transistor array of claim 3, wherein the passivation layer and the dielectric layer comprise a plurality of third contact windows, and each third contact window exposes one of the bottom electrode and one of the scan lines simultaneously.

7. The thin film transistor array of claim 6, wherein each connecting conductive layer is electrically connected to one of the bottom electrodes and one of the scan lines through one of the third contact windows simultaneously.

8. The thin film transistor array of claim 1, wherein the material of the connecting conductive layers is the same as the material of the pixel electrodes.

9. The thin film transistor array of claim 8, wherein the material of the connecting conductive layers and the pixel electrodes comprises ITO or IZO.

10. A thin film transistor array, comprising:
a substrate;
a plurality of scan lines, disposed over the substrate;
a plurality of data lines, disposed over the substrate, wherein the substrate is divided to a plurality of pixel areas by the scan lines and the data lines;
a plurality of thin film transistor, driven by the scan lines and the data lines, wherein each thin film transistor is disposed in one of the pixel areas correspondingly;
a plurality of pixel electrodes, wherein each pixel electrode is disposed in one of the pixel areas and is electrically connected to one of the thin film transistors correspondingly;
a plurality of common lines, disposed over the substrate, wherein a portion of each pixel electrode is located above one of the common lines;
a plurality of bottom electrodes, each bottom electrode is disposed between one of the pixel electrodes and one of the common lines; and
a plurality of connecting conductive layers, each connecting conductive layer is located over and electrically connected between one of the bottom electrodes and one of the common lines correspondingly.

11. The thin film transistor array of claim 10, further comprising a passivation layer disposed between the pixel electrodes and the bottom electrodes as well as the connecting conductive layer and the bottom electrodes.

12. The thin film transistor array of claim 11, further comprising a dielectric layer disposed between the bottom electrodes and the common lines.

13. The thin film transistor array of claim 12, wherein the passivation layer and the dielectric layer comprise a plurality of first contact windows and a plurality of second contact windows, and each first contact window exposes one of the bottom electrode, and each second contact window exposes one of the common lines.

14. The thin film transistor array of claim 13, wherein each connecting conductive layer is electrically connected to one of the bottom electrodes through one of the first contact windows, and each connecting conductive layer is electrically connected to one of the common lines through one of the second contact windows.

15. The thin film transistor array of claim 12, wherein the passivation layer and the dielectric layer comprise a plurality of third contact windows, and each third contact window exposes one of the bottom electrode and one of the common lines simultaneously.

16. The thin film transistor array of claim 15, wherein each connecting conductive layer is electrically connected to one of the bottom electrodes and one of the common lines through one of the third contact windows simultaneously.

17. The thin film transistor array of claim 10, wherein the material of the connecting conductive layers is the same as the material of the pixel electrodes.

18. The thin film transistor array of claim 17, wherein the material of the connecting conductive layers and the pixel electrodes comprises ITO or IZO.
